(19) United States
(12) Patent Application Publication
(10) Pub. No.: US 2010/0243981 A1
(43) Pub. Date: Sep. 30, 2010

(54) Phase-change random access memory device

(76) Inventors: Dae-Hwan Kang, Seoul (KR); Jung-Hoon Park, Seoul (KR)

Correspondence Address: F. CHAU & ASSOCIATES, LLC, 130 WOODBURY ROAD, WOODBURY, NY, 11797, US

(21) Appl. No.: 12/730,460

(22) Filed: Mar. 24, 2010

(30) Foreign Application Priority Data
Mar. 26, 2009 (KR) 10-2009-0025770

(51) Int. Cl. H01L 45/00

(52) U.S. Cl. 257/3; 257/E45.002

(57) ABSTRACT

A phase-change random access memory device includes an isolation layer structure, an insulating interlayer, a spacer, a switching element and a phase-change material (PCM) layer. The isolation layer structure is in a trench on a substrate, defines an active region in the substrate, and has a recess at an upper portion thereof. The insulating interlayer has an opening partially exposing the active region and the isolation layer structure. The spacer is on a sidewall of the opening and fills the recess. The switching element is in the opening on the exposed active region. The PCM layer is electrically connected to the switching element.

### CROSS-REFERENCE TO RELATED APPLICATION

This application claims under 35 USC §119 priority to and the benefit of Korean Patent Application No. 10-2009-0025770, filed on Mar. 26, 2009 in the Korean Intellectual Property Office (KIPO), the entire content of which is incorporated by reference herein.

### BACKGROUND

1. Technical Field

The present disclosure relates to memory devices, and, more particularly, to phase-change random access memory (PRAM) devices and methods of manufacturing the same.

2. Discussion the Related Art

PRAM devices use the difference in resistance of a material in different phases for storing data. That is, a reversible phase transition of a phase-change material (PCM), such as germanium-antimony-tellurium (GST), by an applied pulse may be used for storing data in the PRAM devices.

The PRAM devices typically include a switching element and a PCM layer electrically connected thereto. For example, a diode or a transistor may serve as the switching element.

PRAMs use the behavior of chalcogenide glass, which can be “switched” between two states, crystalline and amorphous, with the application of heat. Chalcogenide is a chemical compound consisting of at least one chalcogen ion, chalcogen being a chemical element in the oxygen family of the periodic table, and at least one more electropositive element, electropositivity being a measure of an element's ability to donate electrons and therefore form positive ions. Such PRAMs are becoming one of a number of new memory technologies that are attempting to compete with the popular flash memories

### SUMMARY

An exemplary embodiment provides a PRAM device having a diode as a switching element.

An exemplary embodiment also provides a method of manufacturing a PRAM device having a diode as a switching element.

According to an exemplary embodiment a phase-change random access memory device includes an isolation layer structure in a trench on a substrate, the isolation layer structure defining an active region in the substrate and having a recess at an upper portion thereof. An insulating interlayer has an opening partially exposing the active region and the isolation layer structure. A spacer is on a sidewall of the opening, the spacer filling the recess. A switching element is in the opening on the exposed active region. A phase-change material layer is electrically connected to the switching element.

The isolation layer structure may include a first oxide layer pattern, a nitride layer pattern and a second oxide layer pattern sequentially stacked on the trench, the first oxide layer pattern and the nitride layer pattern being conformally formed on the trench, and the second oxide layer pattern filling a remaining portion of the trench.

The nitride layer pattern may have a top surface lower than a top surface of the first oxide layer pattern and the second oxide layer pattern, such that the recess is on the nitride layer pattern.

The spacer may cover upper portions of the first oxide layer pattern, the second oxide layer pattern and the nitride layer pattern.

The spacer may not completely fill the recess.

The switching element may be a diode.

The switching element may include a first epitaxial layer pattern and a second epitaxial layer pattern sequentially stacked, the first epitaxial layer pattern and the second epitaxial layer pattern may be doped with a first impurity and a second impurity, respectively, and the first impurity and the second impurity may have conductive types different from each other.

The phase-change random access memory device may further include a conductive layer at an upper portion of the active region, the conductive layer doped with a third impurity having a conductive type substantially the same as that of the first impurity.

The substrate may include single crystalline silicon, and the switching element may include single crystalline silicon having a direction of Miller Index substantially the same as that of the substrate.

According to an exemplary embodiment a method of manufacturing a phase-change random access memory device may include forming an isolation layer structure on a trench in a substrate to fill the trench, the isolation layer structure defining an active region of the substrate, forming an insulating interlayer on the substrate, the insulating interlayer having an opening partially exposing the active region and the isolation layer structure, removing an exposed upper portion of the isolation layer structure to form a recess, forming a spacer on a sidewall of the opening to fill the recess, forming a switching element in the opening to be electrically connected to the active region, and forming a phase-change material layer electrically connected to the switching element.

Forming the isolation layer structure may include forming a first oxide layer pattern conformally on a bottom and a sidewall of the trench, forming a nitride layer pattern conformally on the first oxide layer pattern, and forming a second oxide layer pattern on the nitride layer pattern to fill a remaining portion of the trench.

Removing the exposed upper portion of the isolation layer structure to form the recess may include removing an upper portion of the nitride layer pattern.

The method may further include implanting impurities into the active region of the substrate to form a conductive layer.

Forming the switching element in the opening may include performing an epitaxial growth process on the conductive layer.

According to an exemplary embodiment a phase-change random access memory device includes a substrate having an active region defined by isolation structures. A conductive layer is formed on a surface of the active region. An isolation layer is formed on the substrate and has an opening over the active region. A diode has a first epitaxial layer and a second epitaxial layer stacked in the opening, the first epitaxial layer contacting the conductive layer. An ohmic layer is in the opening and contacts the second epitaxial layer. A phase-change structure is in the opening, the phase change structure having a first electrode contacting the ohmic layer, a second electrode, and a phase-change material between and contacting the first electrode and the second electrode. The diode is isolated from the isolation structures and from the isolation layer by spacers formed on walls of the opening.

The phase-change material may be a chalcogenide including germanium-antimony-tellurium.

The conductive layer may be doped with impurities having a conductive type different from a conductive type of the substrate.

The first epitaxial layer may include impurities substantially the same as the impurities of the conductive layer and the second epitaxial layer may include impurities having a conductive type different from the impurities of the first epitaxial layer.

An area of the first electrode contacting the phase-change material layer may be less than an area of the second electrode contacting the phase-change material layer.

### BRIEF DESCRIPTION OF THE DRAWINGS

FIGS. 1, 2, 3, 4, 5, 6, 7, 8, 9 and 10 are cross-sectional views illustrating a method of manufacturing a PRAM device in accordance with an exemplary embodiment of the present inventive concept.

FIG. 11 is a cross-sectional view illustrating a PRAM device in accordance with an exemplary embodiment.

### DETAILED DESCRIPTION OF THE EMBODIMENTS

Exemplary embodiments of the present inventive concept will be described more fully hereinafter with reference to the accompanying drawings. Like numerals refer to like elements throughout. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present.

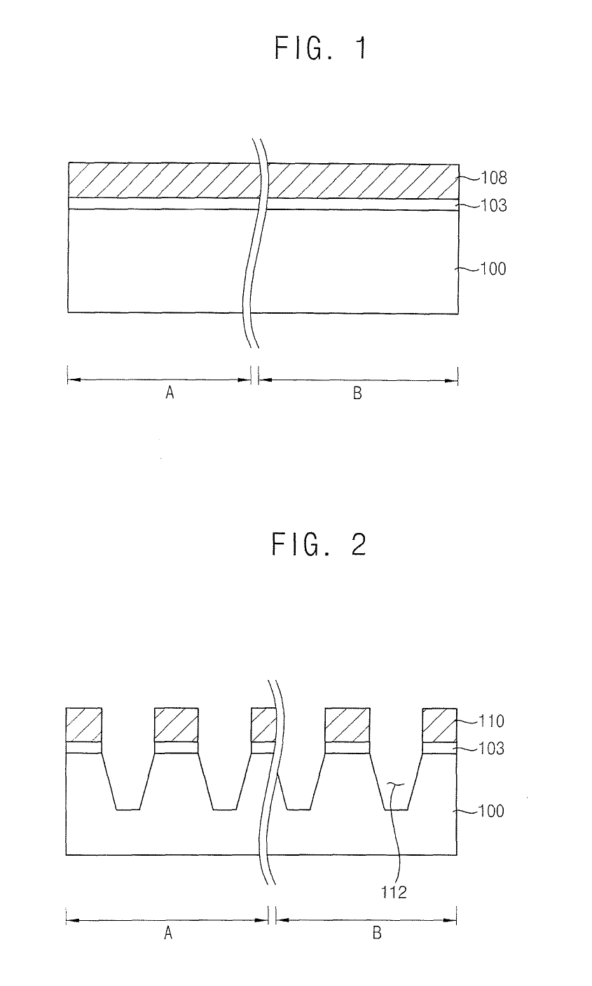

Referring now to FIG. 1, a pad oxide layer 103 and a mask layer 108 may be sequentially formed on a substrate 100.

The substrate 100 may include a semiconductor substrate. For example, the substrate 100 may include a silicon substrate, a germanium substrate, a silicon-germanium substrate, a silicon-on-insulator (SOI) substrate, a germanium-on-insulator (GOI) substrate, or the like. In an exemplary embodiment, the substrate 100 may include a single crystalline silicon substrate. The substrate 100 may include a cell region A and a peripheral region B.

The pad oxide layer 103 may be formed by a thermal oxidation process. In an exemplary embodiment, the pad oxide layer 103 may be formed to have a thickness of about 100 Å to about 1000 Å. The mask layer 108 may be formed using a nitride. In an exemplary embodiment, the mask layer 108 may be formed to have a thickness of about 1000 Å.

Referring to FIG. 2, the mask layer 108 may be patterned to form a mask 110. The pad oxide layer 103 and the substrate 100 may be partially removed using the mask 110 as an etching mask to form a trench 112 at an upper portion of the substrate 100. The trench 112 may have a sidewall angled to a bottom of the trench 112. In an exemplary embodiment, a plurality of trenches 112 may be formed both in the cell region A and in the peripheral region B of the substrate 100. The trenches 112 in the cell region A may be spaced apart closer to each other than those in the peripheral region B.

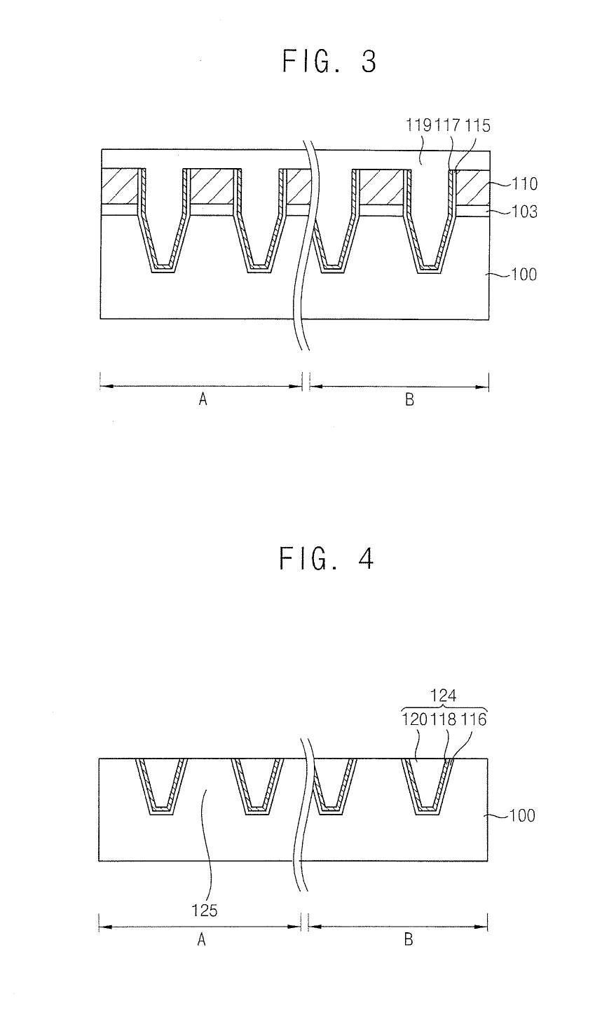

Referring to FIG. 3, a first oxide layer 115 may be formed on bottoms and sidewalls of the trenches 112. The first oxide layer 115 may be formed by a thermal oxidation process. A nitride layer 117 may be formed on the first oxide layer 115. The first oxide layer 115 and the nitride layer 117 may help alleviate damage to the substrate 100 generated during the formation of the trenches 112. Additionally, the nitride layer 117 may reduce leakage current. A second oxide layer 119 may be formed on the nitride layer 117 and the mask 110 to fill the trenches 112. The nitride layer and the second oxide layer 119 may be formed by a chemical vapor deposition (CVD) process, a sputtering process, an atomic layer deposition (ALD) process or a plasma enhanced chemical vapor deposition (PE-CVD) process, or the like. The second oxide layer 119 may be formed using borophosphor silicate glass (BPSG), tonen silazene (TOSZ), undoped silicate glass (USG), spin on glass (SOG), flowable oxide (FOX), tetraethylortho silicate (TEOS), high density plasma chemical vapor deposition (HDP-CVD) oxide, or the like. Alternatively, the second oxide layer 119 may be formed using a middle temperature oxide (MTO).

Referring to FIG. 4, a plurality of isolation layer structures 124 may be formed on the nitride layer 118 to fill the trenches 112. Particularly, an upper portion of the second oxide layer 119 may be planarized until a top surface of the mask 110 is exposed. The planarization process may be performed by a chemical mechanical polishing (CMP) process and/or an etch back process. The mask 110 and upper portions of the nitride layer 117 and the first and second oxide layers 115, 119 may be removed to form the isolation layer structures 124 each of which may include a first oxide layer pattern 116, a nitride layer pattern 118 and a second oxide layer pattern 120 sequentially stacked on the bottoms and the sidewalls of the trenches 112. The pad oxide layer 103 may be also removed. The isolation layer structures 124 may define in the substrate 100 an active region 125 and a field region which typically surrounds the active region.

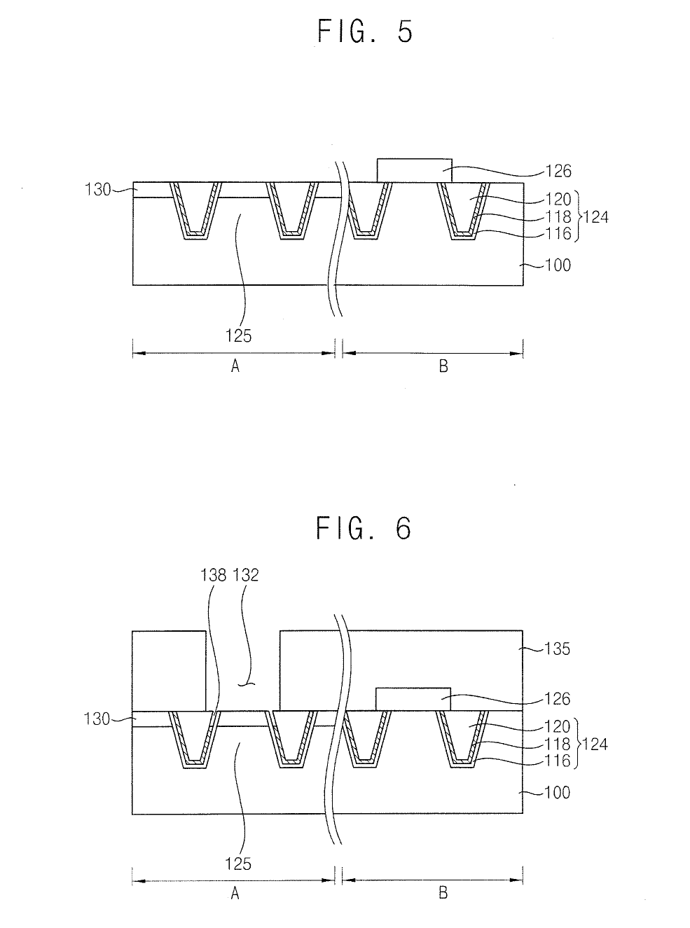

Referring to FIG. 5, a gate electrode 126 may be formed on the substrate 100 in the peripheral region B, and a conductive layer 130 may be formed at upper portions of the substrate 100 in the cell region A. The gate electrode 126 may be formed by a photolithography process. The conductive layer 130 may be formed by implanting first impurities onto the substrate 100. The conductive layer 130 may serve as a word line, such as in a memory array. For example, n-type impurities may be implanted into the active region in the cell region A to form the conductive layer 130. A heat treatment process may be further performed on the substrate 100.

Referring to FIG. 6, an insulating interlayer 135 may be formed on the substrate 100 to cover the gate electrode 126. The insulating interlayer 135 may be formed by a CVD process, a sputtering process, an ALD process, or a PE-CVD process. The insulating interlayer 135 may be formed using BPSG, TOSZ, USG, SOG, FOX, TEOS, HDP-CVD oxide, or the like. Alternatively, the insulating interlayer 135 may be formed using silicon nitride.

The insulating interlayer 135 may be partially removed to form an opening 132 exposing the conductive layer 130 and a portion of the isolation layer structures 124. The removal may be performed by a photolithography process. The portion of the isolation layer structures 124 exposed by the opening 132 may include top surfaces of the first oxide layer pattern 116, the second oxide layer pattern 120 and the nitride layer pattern 118. In an exemplary embodiment, the opening 132 may expose top surfaces of adjacent isolation layer structures 124. Alternatively, the opening 132 may expose a top surface of the isolation layer structures 124. When the insulating interlayer 135 includes silicon nitride, the opening 132 may expose the silicon nitride.

An upper portion of the nitride layer pattern 118 may be removed to form a recess 138. The recess 138 may expose upper portions of the first and second oxide layer patterns 116, 120. The removal may be performed using an etchant having an etching selectivity with respect to the first and second oxide layer patterns 116, 120, e.g., using phosphoric acid. Alternatively, the upper portion of the nitride layer pattern 118 may be removed by a dry etching process.

In an exemplary embodiment, the isolation layer structures 124 in the peripheral region B may be covered with the insulating interlayer 135, and thus an upper portion of the nitride layer pattern 118 in the peripheral region B would not be removed.

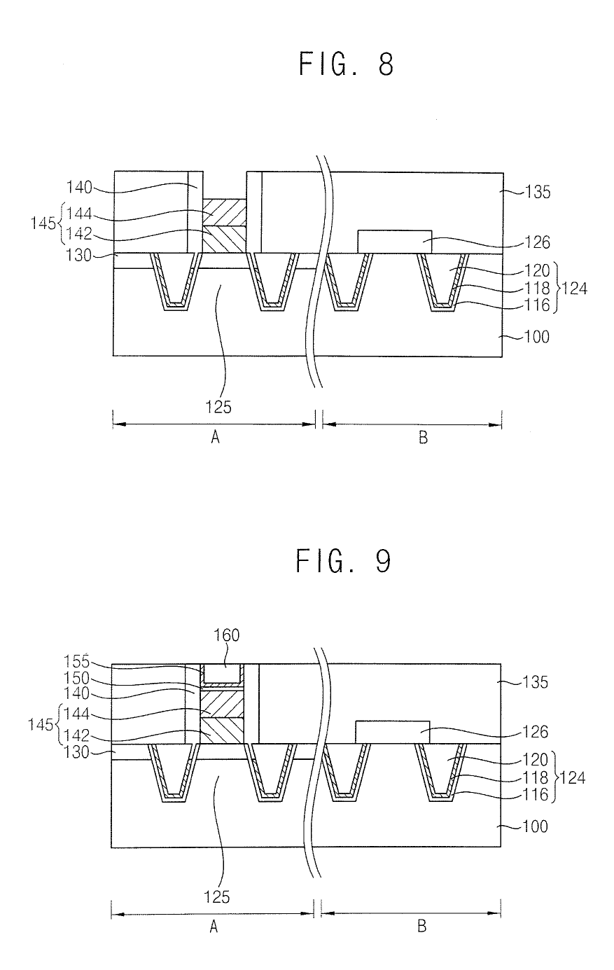

The nitride layer pattern 118 would not contact a diode 145 (see FIG. 8) subsequently formed because of the recess 138, thereby improving the characteristics of the diode 145.

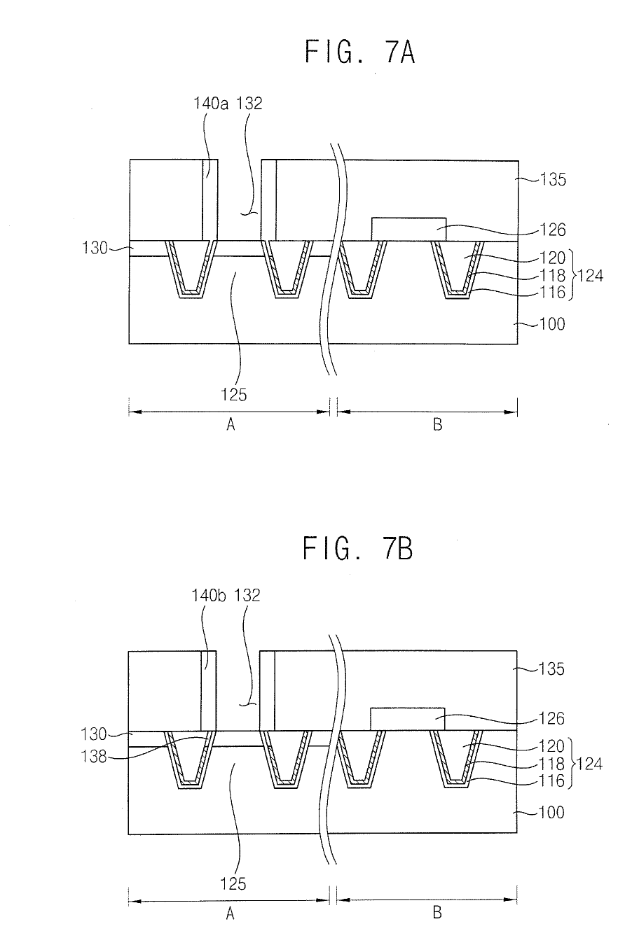

Referring to FIG. 7A, a first spacer 140a may be formed on a sidewall of the opening 132. Particularly, a first spacer layer may be formed on the exposed substrate 100, the exposed upper portions of the first and second oxide layer patterns 116, 120, the exposed top surface of the nitride layer pattern 118, and the insulating interlayer 135 to fill the recess 138 and the opening 132. The first spacer layer may be formed by a CVD process or a low pressure chemical vapor deposition (LPCVD) process. An anisotropic etching process may be performed on the substrate 100 to form the first spacer 140a that fills the recess 138 and is on the sidewalls of the opening 132. Thus, the nitride layer pattern 118 would not be exposed by the opening 132. The first spacer 140a may prevent an epitaxial layer, which may be subsequently grown, from growing from the insulating interlayer 135. When the silicon nitride of the insulating interlayer 135 is exposed by the opening 132, the first spacer 140a would cover the silicon nitride of the insulating interlayer 135 so that the epitaxial layer does not contact the silicon nitride. Before the epitaxial layer is grown, a cleaning process may be further performed on the substrate 100.

Alternatively, referring to FIG. 7B, a second spacer 140b may not completely fill the recess 138. Thus, a void may be formed in the recess 138 to further help isolate the diode.

In an exemplary embodiment, the first or second spacer 140a, 140b might not cover the first oxide layer pattern 116, however, the nitride layer pattern 118 would be covered by the first or second spacer 140a, 140b.

In FIGS. 8 to 10, both the first and second spacers 140a, 140b may be referred to as a spacer 140.

Referring to FIG. 8, the diode 145 may be formed in the opening 132. The diode 145 may include a first epitaxial layer pattern 142 and a second epitaxial layer pattern 144 sequentially stacked on the exposed portion of the substrate 100. The diode 145 would not completely fill the opening 132.

Particularly, the diode 145 may be formed as follows. An epitaxial growth process may be performed using the exposed portion of the substrate 100 as a seed, thereby forming the epitaxial layer. The epitaxial layer may be formed to have a crystalline structure, e.g., in a direction per the Miller Index notation system in crystallography for planes and directions in crystal lattices, substantially the same as that of the substrate 100. The epitaxial layer would not be affected by the insulating interlayer 135 because of the first spacer 140. Additionally, the epitaxial layer would not contact the nitride layer pattern 118, and thus would not be affected thereby.

In an exemplary embodiment, the epitaxial layer may have a single crystalline structure and include impurities substantially the same conductive type as that of the first impurities because the first impurities of the conductive layer 130 may diffuse into the epitaxial layer.

Second impurities may be implanted into an upper portion of the epitaxial layer to form the second epitaxial layer pattern 144. The remaining portion of the epitaxial layer may be referred to as the first epitaxial layer pattern 142. The second impurities may have a conductive type different from that of the first impurities. The first and second epitaxial layer patterns 142, 144 may define the diode 145. In an exemplary embodiment, the first and second epitaxial layer patterns 142, 144 may include n-type impurities and p-type impurities, respectively. The diode 145 may serve as a switching element. A cleaning process may be further performed.

Referring to FIG. 9, an ohmic layer 150, a lower electrode 155 and a filler 160 may be formed on the diode 145 to fill the remaining portion of the opening 132.

The ohmic layer 150 may be formed using a metal silicide such as cobalt silicide, titanium silicide, tantalum silicide, nickel silicide, tungsten silicide, or the like. The ohmic layer 150 may be formed by depositing a metal on the diode 145 and performing a heat treatment thereon. The deposition of the metal may be performed by a sputtering process, an ALD process, or the like. The ohmic layer 150 may be formed on a top surface of the diode 145.

The lower electrode 155 may be conformally formed on the ohmic layer 150 and a sidewall of the opening 132. Particularly, a conductive layer may be formed on the ohmic layer 150, the sidewall of the opening 132 and the insulating interlayer 135. An upper portion of the conductive layer on the insulating interlayer 135 may be planarized until a top surface of the insulating interlayer 135 is exposed to form the lower electrode 155. The lower electrode 155 may be formed using a metal such as titanium, tantalum, aluminum, tungsten, molybdenum, niobium, zirconium, or the like. These may be used alone or in a combination thereof.

A filling layer may be formed on the lower electrode 155 and the insulating interlayer 135 to fill the remaining portion of the opening 132. The filling layer may be formed using titanium nitride, tantalum nitride, aluminum nitride, tungsten nitride, molybdenum nitride, niobium nitride, zirconium nitride, or the like. An upper portion of the filling layer may be planarized until the top surface of the insulating interlayer 135 is exposed to form the filler 160.

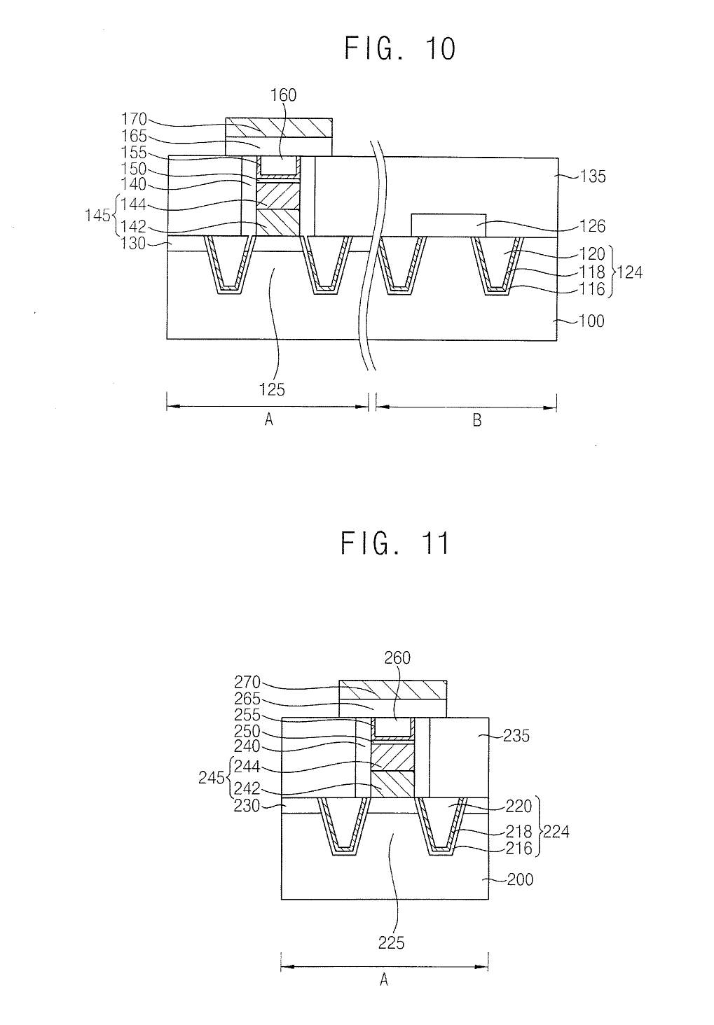

The filler 160 may reduce the area of the lower electrode 155 contacting a PCM layer pattern 165 (see FIG. 10) subsequently formed. Thus, the phase of the PCM layer pattern 165 may be easily changed by less current.

Referring to FIG. 10, the PCM layer pattern 165 and an upper electrode 170 may be formed on the lower electrode 155.

Particularly, a PCM layer and an upper electrode layer may be sequentially formed on the insulating interlayer 135, the lower electrode 155, the filler 160 and the spacer 140. The PCM layer and the upper electrode layer may be formed by a PVD process, an ALD process, a CVD process, or the like. The PCM layer may be formed using GST.

The upper electrode layer and the PCM layer may be patterned to form the upper electrode 170 and the PCM layer pattern 165, respectively, thereby manufacturing the PRAM device.

Hereinafter, the PRAM device manufactured by the above processes will be explained in more detail with reference to FIG. 10.

The PRAM device may include the substrate 100 having the cell region A and the peripheral region B, the isolation layer structures 124 in trenches 112 (see FIG. 2) on the substrate 100, the active region of the substrate 100, the diode 145 on the active region, the lower electrode 155 on the diode 145, the PCM layer pattern 165 and the upper electrode 170.

Each of the isolation layer structures 124 may include a first oxide layer pattern 116, a nitride layer pattern 118, and a second oxide layer pattern 120. The first oxide layer pattern 116 may be conformally formed on the bottom and the sidewall of the trench 112. The nitride layer pattern 118 may be conformally formed on the first oxide layer pattern 116. The second oxide layer pattern 120 may fill the remaining portion of the trench 112. The isolation layer structures 124 may define the active region in the substrate 100. The nitride layer pattern 118 may have a top surface lower than those of the first and second oxide layer patterns 116, 120, so that the nitride layer pattern 118 does not contact the diode 145.

The conductive layer 130 doped with impurities may be formed at upper portions of the active region in the cell region A. The impurities may have a conductive type different from that of the substrate 100. For example, when the substrate 100 includes n-type impurities such as phosphorus, arsenic or antimony, the conductive layer 130 may include p-type impurities such as boron, gallium or indium. The conductive layer 130 may serve as a word line. The gate electrode 126 may be formed on the active region in the peripheral region B.

The insulating interlayer 135 having the opening 132 therethrough may be formed on the substrate 100 and on the isolation layer structures 124. The insulating interlayer 135 may partially cover the active region and the isolation layer structures 124 in the cell region A, and cover the peripheral region B. In the cell region A, the insulating interlayer 135 may not cover a portion of the active region and upper portions of the first and second oxide layer patterns 116, 120 and the nitride layer pattern 118. The insulating interlayer 135 may insulate a plurality of PRAM devices from each other. The insulating interlayer 135 may include an oxide, a nitride or an oxynitride. The insulating interlayer 135 may have a single layer or a multi-layered structure including an oxide, at least one nitride layer and/or at least an oxynitride layer sequentially or alternately stacked.

The spacer 140 may be formed on the sidewall of the opening 132 and may contact the portion of the active region and the upper portions of the first and second oxide layer patterns 116, 120 and the top surface of the nitride layer pattern 118, which are not covered by the insulating interlayer 135. Alternatively, the spacer 140 would not contact the top surface of the nitride layer pattern 118 because of the void (see FIG. 7B) between the spacer 140 and the top surface of the nitride layer pattern 118.

The diode 145 may be formed on the conductive layer 130 of the active region of the substrate 100 in the cell region A. The diode 145 may include the first and second epitaxial layer patterns 142, 144 sequentially stacked. The first epitaxial layer pattern 142 may include impurities substantially the same as those of the conductive layer 130. The first epitaxial layer pattern 142 may have a single crystalline structure, e.g., a direction of Miller index, substantially the same as that of the substrate 100. The diode 145 may serve as a switching element. The second epitaxial layer pattern 144 may include impurities having a conductive type different from that of the first epitaxial layer pattern 142.

The ohmic layer 150 may be on the diode 145. The ohmic layer 150 may include a metal silicide. For example, the ohmic layer 150 may include titanium silicide, cobalt silicide, tantalum silicide, tungsten silicide, or the like.

The lower electrode 155 may be on the ohmic layer 150. In an exemplary embodiment, the lower electrode 155 may have a U shape cross-section. Alternatively, the lower electrode 155 may have a cylindrical shape, a ring shape, a cup shape, or the like. The lower electrode 155 may include a metal such as titanium, tantalum, aluminum, tungsten, molybdenum, niobium, zirconium, or the like. These may be used alone or in a combination thereof.

The filler 160 may be on the lower electrode 155 and fill the inside of the U-shaped lower electrode 155. The filler 160 may include a nitride, an oxide or an oxynitride. For example, the filler 160 may include silicon nitride, silicon oxide, silicon oxynitride, or the like. The insulating interlayer 135, the filler 160 and the lower electrode 155 may have a top surface at substantially the same level.

The PCM layer pattern 165 may be on the lower electrode 155, the filler 160 and the first insulating interlayer 135. The PCM layer pattern 165 may have a width wider than that of the lower electrode 155, thereby being formed also on the insulating interlayer 135. The PCM layer pattern 165 may include a chalcogenide containing GST. The chalcogenide may alternatively be doped with carbon, nitride and/or a metal.

The upper electrode 170 may be on the PCM layer pattern 165. The upper electrode 170 may have a width substantially the same as that of the PCM layer pattern 165. The upper electrode 170 may have a single metal layer or a multi-layered structure including a metal layer and a metal nitride layer. For example, the metal layer may include titanium, tungsten, aluminum, nickel, zirconium, molybdenum, ruthenium, palladium, hafnium, tantalum, iridium, platinum, or the like. These may be used alone or in a combination thereof. For example, the metal nitride layer may include titanium nitride, tungsten nitride, aluminum nitride, nickel nitride, zirconium nitride, molybdenum nitride, ruthenium nitride, palladium nitride, hafnium nitride, tantalum nitride, iridium nitride, platinum nitride, or the like. These may be used alone or in a combination thereof.

FIG. 11 is a cross-sectional view illustrating a PRAM device in accordance with an exemplary embodiment. The PRAM device may include a substrate 200 having a cell region A and a peripheral region (not shown), isolation layer structures 224 in trenches on the substrate 200, an active region 225 of the substrate 200, a diode 245 on the active region, a lower electrode 255 on the diode 245, a PCM layer pattern 265 and an upper electrode 270.

Each of the isolation layer structures 224 may include a first oxide layer pattern 216, a nitride layer pattern 218, and a second oxide layer pattern 220. The first oxide layer pattern 216 may be conformally formed on a bottom and a sidewall of the trench. The nitride layer pattern 218 may be conformally formed on the first oxide layer pattern 216. The second oxide layer pattern 220 may fill the remaining portion of the trench. The isolation layer structures 224 may define the active region in the substrate 200. The nitride layer pattern 118 may have a top surface substantially at the same level as those of the first and second oxide layer patterns 116, 120.

A conductive layer 230 doped with impurities may be formed at upper portions of the active region in the cell region A. The impurities may have a conductive type different from that of the substrate 200. For example, when the substrate 200 includes n-type impurities such as phosphorus, arsenic or antimony, the conductive layer 230 may include p-type impurities such as boron, gallium or indium. The conductive layer 230 may serve as a word line.

The insulating interlayer 235 having an opening (not shown) therethrough may be formed on the substrate 200 and the isolation layer structures 224. The insulating interlayer 235 may partially cover the active region and the isolation layer structures 224 in the cell region A. In the cell region A, the insulating interlayer 235 may not cover a portion of the active region and upper portions of the first and second oxide layer patterns 216, 220 and the nitride layer pattern 218. Alternatively, the insulating interlayer 235 may cover the second oxide layer pattern 220 and the nitride layer pattern 218, but not cover a portion of the active region and an upper portion of the first oxide layer pattern 216. The insulating interlayer 235 may insulate a plurality of PRAM devices from each other. The insulating interlayer 235 may include an oxide, a nitride or an oxynitride. The insulating interlayer 235 may have a single layer or a multi-layered structure including an oxide, at least one nitride layer and/or at least an oxynitride layer sequentially or alternately stacked.

The spacer 240 may be formed on the sidewall of the opening and may contact the upper portions of the first and second oxide layer patterns 216, 220 and the nitride layer pattern 218, which are not covered by the insulating interlayer 235. Alternatively, when the insulating interlayer 235 covers the second oxide layer pattern 220 and the nitride layer pattern 218, the spacer 240 may contact an upper portion of the first oxide layer patterns 216, which are not covered by the insulating interlayer 235.

The diode 245 may be formed on the conductive layer 230 of the active region of the substrate 200 in the cell region A. The diode 245 does not contact the nitride layer pattern 218 because of the spacer 240. The diode 245 may include first and second epitaxial layer patterns 242, 244 sequentially stacked. The first epitaxial layer pattern 242 may include impurities substantially the same as those of the conductive layer 230. The first epitaxial layer pattern 242 may have a single crystalline structure, e.g., a direction of Miller index, substantially the same as that of the substrate 200. The diode 245 may serve as a switching element. The second epitaxial layer pattern 244 may include impurities having a conductive type different from that of the first epitaxial layer pattern 242.

An ohmic layer 250 may be on the diode 245. The lower electrode 255 may be on the ohmic layer 250. The lower electrode 255 may have a U shape cross-section. A filler 260 may be on the lower electrode 255 and fill the inside of the U-shaped lower electrode 255. The PCM layer pattern 265 may be on the lower electrode 255, the filler 260 and the first insulating interlayer 235. The upper electrode 270 may be on the PCM layer pattern 265.

A PRAM device in accordance with at least one of the exemplary embodiments can offer improved performance over flash memories in applications where writing quickly is important, both because the PCM can be switched by the diode more quickly, and also because single bits may be changed to either 1 or 0 without needing to first erase an entire block of cells.

Although practical exemplary embodiments have been described, those skilled in the art will readily appreciate that many modifications are possible in the exemplary embodiments without materially departing from the present inventive concept. Accordingly, the specific exemplary embodiments disclosed, modifications to the disclosed exemplary embodiments, as well as other exemplary embodiments, are intended to be included within the scope of the appended claims.

1. A phase-change random access memory device, comprising:
an isolation layer structure in a trench on a substrate, the isolation layer structure defining an active region in the substrate and having a recess at an upper portion thereof;
an insulating interlayer having an opening partially exposing the active region and the isolation layer structure;
a spacer on a sidewall of the opening, the spacer filling the recess;
a switching element in the opening on the exposed active region; and
a phase-change material layer electrically connected to the switching element.

2. The phase-change random access memory device of claim 1, wherein the isolation layer structure includes a first oxide layer pattern, a nitride layer pattern and a second oxide layer pattern sequentially stacked on the trench, the first oxide layer pattern and the nitride layer pattern being conformally formed on the trench, and the second oxide layer pattern filling a remaining portion of the trench.

3. The phase-change random access memory device of claim 2, wherein the nitride layer pattern has a top surface lower than a top surface of the first oxide layer pattern and the second oxide layer pattern, such that the recess is on the nitride layer pattern.

4. The phase-change random access memory device of claim 2, wherein the spacer covers upper portions of the first oxide layer pattern, the second oxide layer pattern and the nitride layer pattern.

5. The phase-change random access memory device of claim 1, wherein the spacer does not completely fill the recess.

6. The phase-change random access memory device of claim 1, wherein the switching element is a diode.

7. The phase-change random access memory device of claim 6, wherein the switching element includes a first epitaxial layer pattern and a second epitaxial layer pattern sequentially stacked, the first epitaxial layer pattern and the second epitaxial layer pattern being doped with a first impurity and a second impurity, respectively, and the first impurity and the second impurity having conductive types different from each other.

8. The phase-change random access memory device of claim 7, further comprising a conductive layer at an upper portion of the active region, the conductive layer doped with a third impurity having a conductive type substantially the same as that of the first impurity.

9. The phase-change random access memory device of claim 1, wherein the substrate includes single crystalline silicon, and the switching element includes single crystalline silicon having a direction of Miller Index substantially the same as a direction of Miller Index of the substrate.

10.-14. (canceled)

15. A phase-change random access memory device, comprising:
a substrate having an active region defined by isolation structures;
a conductive layer formed on a surface of the active region;
an isolation layer formed on the substrate and having an opening over the active region;
a diode having a first epitaxial layer and a second epitaxial layer stacked in the opening, the first epitaxial layer contacting the conductive layer;
an ohmic layer in the opening that contacts the second epitaxial layer; and
a phase-change structure in the opening, the phase change structure having a first electrode contacting the ohmic layer, a second electrode, and a phase-change material between and contacting the first electrode and the second electrode;
wherein the diode is isolated from the isolation structures and from the isolation layer by spacers formed on walls of the opening.

16. The phase-change random access memory device of claim 15, wherein the phase-change material is a chalcogenide including germanium-antimony-tellurium.

17. The phase-change random access memory device of claim 16, wherein the conductive layer is doped with impurities having a conductive type different from a conductive type of the substrate.

18. The phase-change random access memory device of claim 17, wherein the first epitaxial layer includes impurities substantially the same as the impurities of the conductive layer and the second epitaxial layer includes impurities having a conductive type different from the impurities of the first epitaxial layer.

19. The phase-change random access memory device of claim 15, wherein an area of the first electrode contacting the phase-change material layer is less than an area of the second electrode contacting the phase-change material layer.
